(19) United States
(12) Patent Application Publication
(10) Pub. No.: US 2009/0147494 A1
(43) Pub. Date: Jun. 11, 2009

(54) ELECTRONIC DEVICE AND SLOT

(75) Inventors: Hideyuki IIDA, Kawasaki (JP); Yoshiaki HIRATSUKA, Kawasaki (JP); Keisuke NAKAMURA, Kawasaki (JP); Yoshiro TANAKA, Kawasaki (JP); Hisashi YOSHINAGA, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/269,930

(22) Filed: Nov. 13, 2008

(30) Foreign Application Priority Data
Dec. 5, 2007 (JP) 2007-314728

(51) Int. Cl. H05K 9/00

(52) U.S. Cl. 361/818

(57) ABSTRACT

An electronic device includes a casing having an opening, a cover that covers the opening, a slot connector provided on a board arranged in the casing, and a conducting member that is provided at the slot and that electrically connects the printed circuit board to the cover.

### BACKGROUND

1. Field of the Invention

The present technique relates electronic devices and slots. More particularly, the present technique relates to an electronic device and a slot capable of reducing high-frequency noises.

2. Description of the Related Art

For example, an increase in a clock frequency, an increase in mounting density of a printed circuit board, and a decrease in weight of an apparatus make it more difficult to take measures against electromagnetic interference (EMI) (measures for radio noises) in electronic devices, such as notebook personal computers. In particular, regarding measures for radio waves emitted from a memory, a slot (slot connector) of a memory (DIMM: dual inline memory module) is one of main units subjected to the measures.

High-frequency noises emitted from a memory can be reduced by grounding. Accordingly, a printed circuit board signal ground (hereinafter, sometimes abbreviated as a board SG) provided in a printed circuit board on which a slot is mounted is electrically connected to a casing frame ground (hereinafter, sometimes abbreviated as a casing FG) of a casing (chassis) of an electronic device, whereby the above-described measures against the EMI are taken.

Regarding techniques according to the related art, additional measures, such as arrangement of a gasket (a spacer filling a gap and electrically connecting components) around a slot of a memory and adhesion of a radio wave absorber sheet, are mainly employed as the measures against the EMI of a memory contained in an electronic device. In addition, as gasket-employing measures, a method for shielding the EMI by providing a relatively large gasket between a board SG and a casing FG and a method for connecting a latch portion (catches on both sides for fixing the DIMM) of a slot to a board SG and connecting this latch portion to a casing FG with a gasket are available.

A board SG arranged around a memory on a printed circuit board serves as a radiation source of high-frequency noises of the memory. Accordingly, conductive connection of the board SG arranged around the memory on the printed circuit board to a casing FG can offer a significant shielding effect.

However, since the casing FG generally is a cover allowing a memory to be exchanged, the casing FG is a movable component to be attached to and detached from a casing of an electronic device at the time of attachment and detachment of a DIMM, respectively. Thus, in gasket-employing shielding, which has been used in the related art, a position of a gasket may be undesirably shifted from an appropriate position due to the attachment and detachment of the cover and, in the worst case, the gasket may fall off, due to which connection between the board SG and the casing FG becomes undesirably unstable. Additionally, when the gasket falls onto the printed circuit board, a short may be caused between wires and electronic components formed on the printed circuit board.

### SUMMARY

It is an object of the present technique to provide an electronic device and a slot capable of realizing shielding of high-frequency noises radiated from a memory with a simple structure at a high reliability.

According to an aspect of an embodiment, an electronic device includes a casing having an opening, a cover removably attached to the casing to cover the opening, a slot mounted on a board arranged in the casing, and a conducting member that is provided at the slot and that electrically connects the board to the cover.

According to the disclosed electronic device, the board and the cover can be readily and certainly connected without using a gasket by providing a conducting member for electrically connecting the board and the cover at a slot having a predetermined height with respect to the board. Accordingly, even if a source of high-frequency noises is mounted on a board, EMI countermeasures against those noises can be taken implemented by the board and the cover.

### BRIEF DESCRIPTION OF THE DRAWINGS

FIG. 1 is an enlarged perspective view of an area near a slot of an electronic device according to an embodiment of the present technique;

FIG. 2 is a perspective view from a bottom face side of an electronic device according to an embodiment of the present technique;

FIG. 3 is a perspective view showing a state where a cover is removed in a state shown in FIG. 2;

FIG. 4 is an enlarged sectional view showing an area near a slot of an electronic device according to an embodiment of the present technique;

FIG. 5 is a diagram of a slot viewed from an opening formed in a casing of an electronic device;

FIGS. 6A to 6C are diagrams for illustrating alterations of a conducting member;

FIGS. 7A and 7B are diagrams for illustrating alterations of a connection configuration of a conducting member and a board signal ground;

FIGS. 8A to 8C are diagrams for illustrating alterations of a connection configuration of a conducting member and a cover;

FIG. 9 is a perspective view showing an example case where the present technique is applied to a double slot connector;

FIGS. 10A and 10B are diagrams for illustrating advantages of an electronic device according to an embodiment (horizontal wave); and

FIGS. 11A and 11B are diagrams for illustrating advantages of an electronic device according to an embodiment (vertical wave).

### DESCRIPTION OF THE PREFERRED EMBODIMENTS

Embodiments of the present technique will now be described with reference to the accompanying drawings.

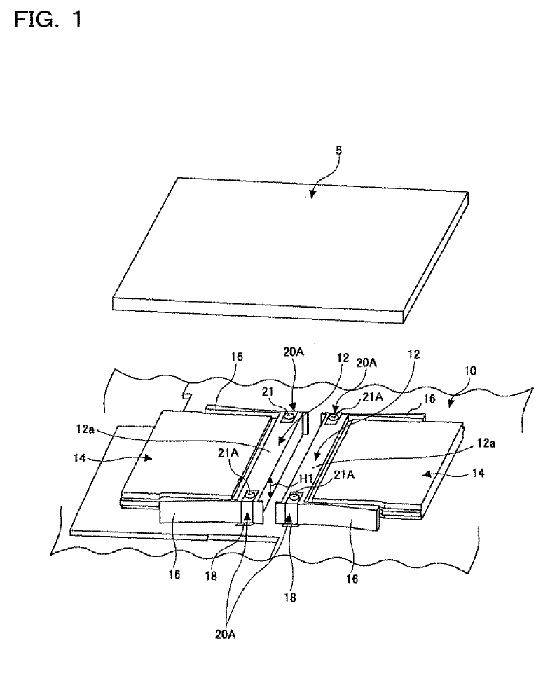

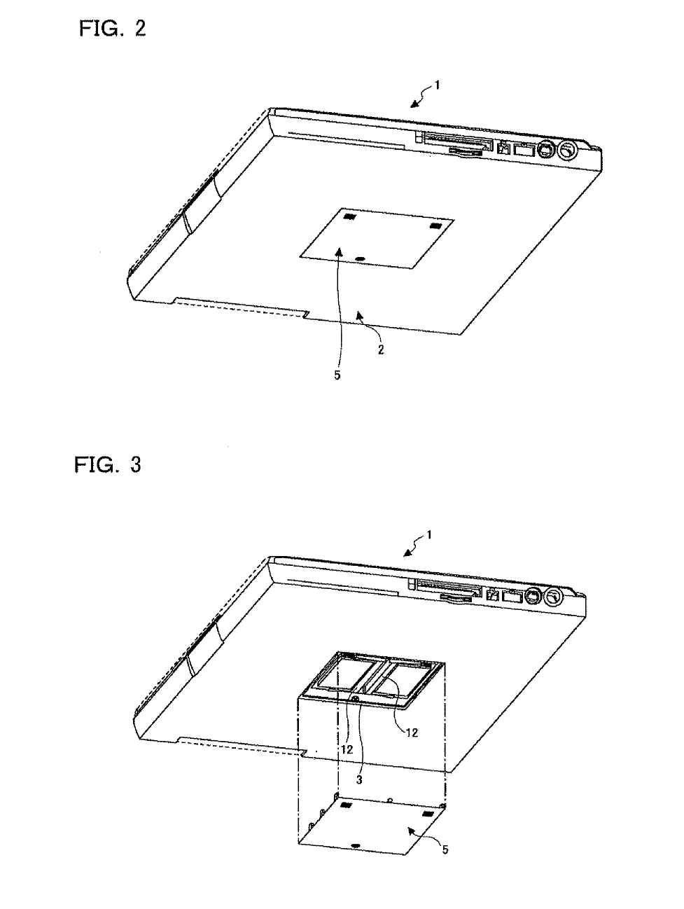

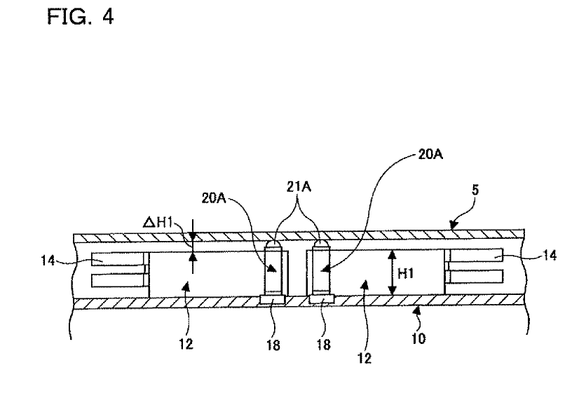

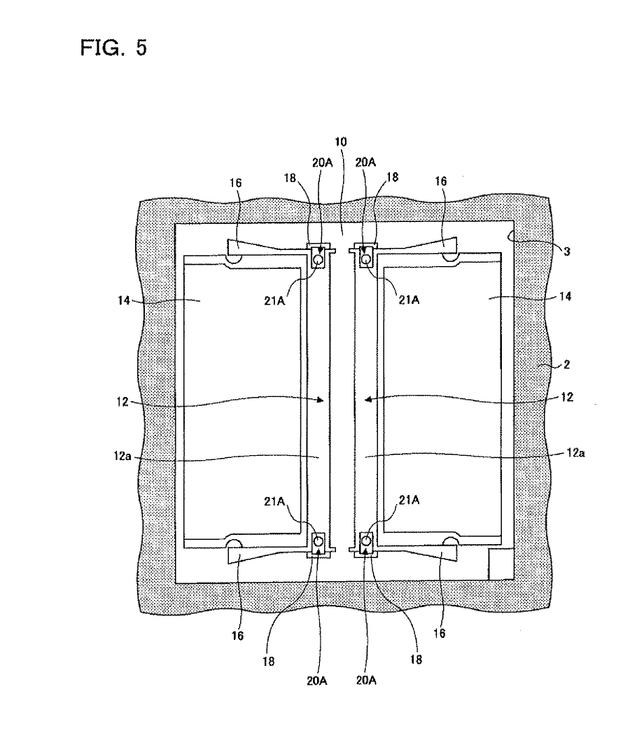

FIGS. 1 to 5 are diagrams for illustrating an electronic device 1 according to an embodiment of the present technique. More specifically, FIG. 1 is an enlarged perspective view showing major components of the electronic device 1. FIGS. 2 and 3 are diagrams of the electronic device 1 viewed from a bottom face. FIG. 4 is a sectional view showing the major components of the electronic device 1. FIG. 5 is a plan view showing the major components of the electronic device 1.

The electronic device 1 may be, for example, a notebook personal computer. In the electronic device 1 of this type, a memory is expanded by attaching a DIMM 14 to a slot mounted on a printed circuit board 10. In this embodiment, a slot connector 12 is employed as the slot.

As shown in FIGS. 2 and 3, a cover 5 arranged on a bottom face of a casing 2 is removed to install the DIMM 14 in the casing 2 of the electronic device 1. The cover 5 is provided at an arrangement position of the slot connector 12, to which the DIMM 14 is attached. Accordingly, the slot connector 12 provided on the printed circuit board 10 is exposed to outside from an opening 3 formed in the casing 2 by removal of the cover 5. The DIMM 14 is set to the slot connector 12 through this opening 3, whereby expansion of a memory is carried out.

The cover 5 includes a resin main body and a conductive metal (not shown) arranged inside of the main body (or the cover 5 itself may be formed of a conductive metal). This cover 5 is electrically connected to a conducting member 20A, which will be described later, with being attached to the casing 2, thereby being connected to a printed circuit board signal ground (hereinafter, abbreviated as a board SG) 18 provided in the printed circuit board 10. When the cover 5 is attached to the casing 2, the cover 5 faces the DIMM 14 serving as a radiation source of high-frequency noises. By connecting the cover 5 to the board SG 18 through the conducting member 20A, the cover 5 functions as a casing frame ground (hereinafter, abbreviated as a casing FG) for reducing high-frequency noises emitted from the DIMM 14.

The printed circuit board 10 may be, for example, a multilayer printed circuit board. Various electronic components, such as the slot connector 12, are mounted on the printed circuit board 10. This printed circuit board 10 is fixed to an inner face of the casing 2. In addition, the board SG 18 is formed at a position where the slot connector 12 of the printed circuit board 10 is arranged. This board SG 18 is set equal to a ground potential level.

Two slot connectors 12 are mounted on the printed circuit board 10 to face each other. Each of the slot connectors 12 includes a connector main body 12a and memory-exchange-permitting fixing catches 16 arranged on the respective side of the connector main body 12a.

The connector main body 12a is a resin molded casing. Many connector pins are arranged inside of the connector main body 12a. One end of the connector pin serves as a contact portion electrically connected to the DIMM 14, whereas the other end is soldered to the printed circuit board 10.

In addition, the height of the slot connector 12 (shown as an arrow H1 in FIGS. 1 and 4) is relatively high among electronic components mounted on the printed circuit board 10. Accordingly, as shown in FIG. 4, a clearance shown by an arrow ΔH1 in FIG. 4 is formed between an inner face of the cover 5 and an upper face of the slot connector 12 when the cover 5 is attached to the casing 2. The size of this clearance ΔH1 may be approximately 0.5-3.0 mm, for example.

In addition, the memory fixing catches 16 are provided on the respective sides of the connector main body 12a. When the DIMM 14 is attached to or detached from the slot connector 12, the memory fixing catches 15 deform outwardly. When the DIMM 14 is attached to the slot connector 12, the catches 16 are engaged with the DIMM 14 to fix the DIMM 14.

The conducting member 20A will now be described. The conducting member 20A electronically connects the board SG 18 formed in the printed circuit board 10 to the cover 5. In this embodiment, a conductive metal material (e.g., Cu) is employed as the conducting member 20A.

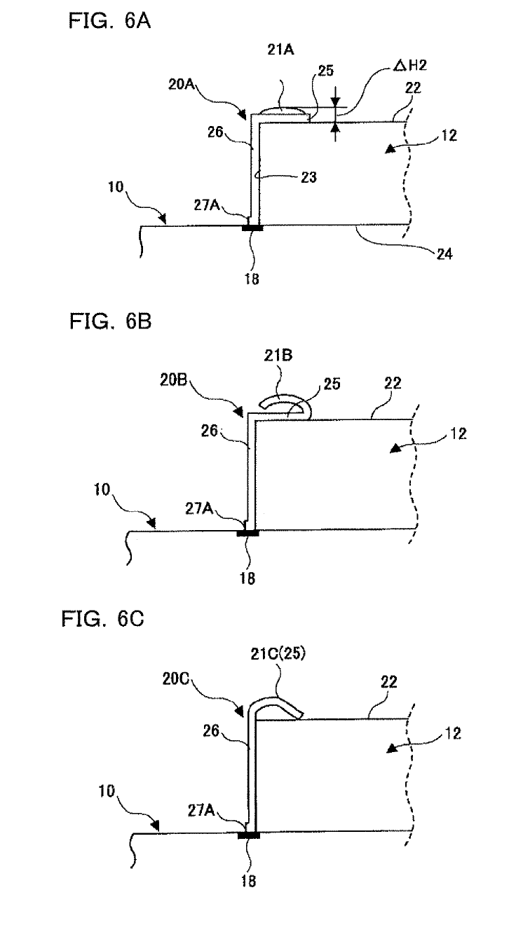

As shown in FIG. 6A, the conducting member 20A includes an upper part 25 extending in the horizontal direction along an upper face of the slot connector 12 (more specifically, the connector main body 12a), a side part 26 extending in the vertical direction along a side face of the slot connector 12, and a lower part 27A extending in the horizontal direction along an upper face of the printed circuit board 10. The upper part 25, the side part 26, and the lower part 27A are formed in an integrated manner. Furthermore, a projecting portion 21A that projects upward is formed at the upper part 25 in the integrated manner. The lower part 27A is electrically connected to the board SG 18 formed in the printed circuit board 10.

In this embodiment, since the conducting member 20A is formed in a shape that is along the contour of the slot connector 12 (more specifically, the connector main body 12a), the conducting member 20A does not interfere other electronic components or devices mounted on the printed circuit board 10 even if the conducting member 20A is provided. In addition, the upper part 25 and the side part 26 of the conducting member 20A are fixed to an upper face 22 and a side face 23, respectively, with an adhesive or a groove provided on the slot connector 12, whereas the lower part 27A is soldered to the board SG 18. Accordingly, since the conducting member 20A is firmly fixed to the slot connector 12, the conducting member 20A does not fall off from the slot connector 12 at the time of removal of the cover 5 and the attachment and detachment of the DIMM 14. Thus, it is possible to prevent circuits or devices mounted on the printed circuit board 10 from being short-circuited due to the conducting member 20A.

The conducting member 20A having the above-described configuration can be formed by, for example, presswork. The projecting portion 21A formed at the upper part 25 is collectively formed in the presswork. Therefore, the projecting portion 21A can be readily formed. In addition, formation of the projecting portion 21A in the presswork in this manner makes the thickness of the projecting portion 21A slightly thinner than other portions, which thus allows the projecting portion 21A to flexibly deform.

Furthermore, a projecting amount ΔH2 (shown by an arrow in FIG. 6A) the projecting portion 21A from the upper face 22 of is set larger than the clearance ΔH1 formed between the inner face of the cover 5 and the upper face of the slot connector 12 when the cover 5 is attached to the casing 2 (ΔH2>ΔH1).

Accordingly, attachment of the cover 5 to the casing 2 presses the projecting portion 21A against the cover 5 to cause the projecting portion 21A to elastically deform. The elastic recovery force is applied to the cover 5. More specifically, the projecting portion 21A presses the cover 5, which allows the conducting member 20A to be electrically connected to the cover 5. FIG. 4 shows a state where the cover 5 is connected to the projecting portion 21A of the conducting member 20A.

As described above, by certainly connecting the conducting member 20A, connected to the board SG 18, to the cover 5 functioning as the casing FG, radiation noises from the memory can be released from the board SG 18 to the cover 5 (the casing FG) through the conducting member 20A if the cover 5 is used as the casing FG for reducing high-frequency noises from the DIMM 14, and thus the radiation noises can be reduced.

In addition, the conducting member 20A utilizes the slot connector 12 and is fixed to the slot connector 12. Thus, even if the cover 5 is removable from the casing 2, the conducting member 20A does not fall off from the slot connector 12 at the time of the attachment and detachment of the cover 5, unlike a conventional case of using a gasket. Therefore, it is possible to prevent a short from being caused between wires and between electronic components formed on the printed circuit board 10.

Additionally, the board SG 18 formed in the printed circuit board 10 is separated from the cover 5. By forming the conducting member 20A using the slot connector 12 as a so-called support, the necessity for making the conducting member 20A stand on the printed circuit board 10 is eliminated. Accordingly, even with the conducting member 20A press-formed from a thin plate as in this embodiment, it is possible to electrically connect the conductive member 20A to the cover 5. Thus, a cost for materials and an assembly cost can be reduced.

Furthermore, the conducting member 20A may be formed separately from the slot connector 12 or may be formed integrally with the slot connector 12. When the conducting member 20A is formed separately from the slot connector 12, mounting of the slot connector 12 on the printed circuit board 10 and mounting of the conducting member 20A on the printed circuit board 10 are performed separately. On the other hand, when the conducting member 20A is formed integrally with the slot connector 12, the conducting member 20A can be mounted on the printed circuit board 10 at the same time of mounting of the slot connector 12 on the printed circuit board 10. Thus, the attachment process can be simplified.

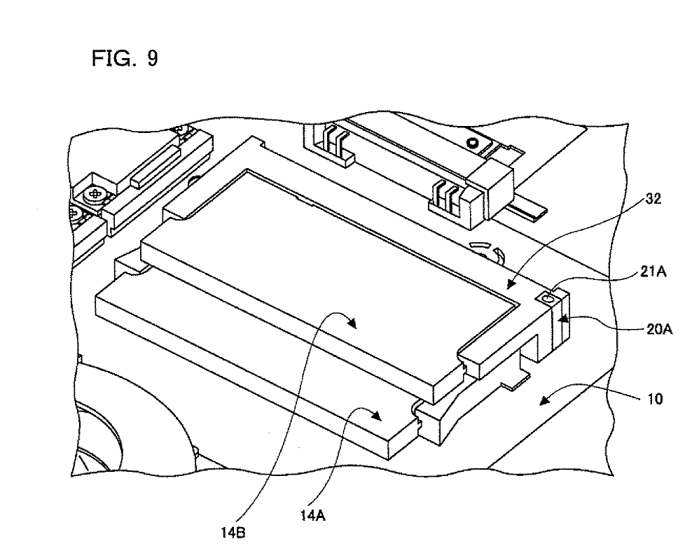

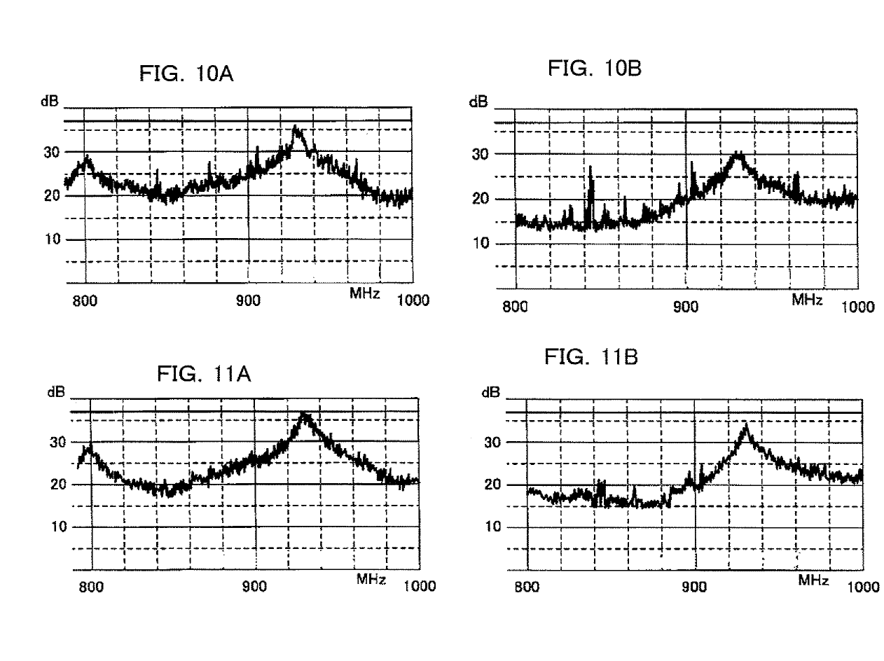

FIGS. 10A to 11B are diagrams for illustrating advantages offered by the electronic device 1 according to an embodiment. In each drawing, the horizontal axis represents a frequency (MHz), whereas the vertical axis represents a noise level (dB).

FIG. 10A shows a horizontal wave of high-frequency noises radiated from a DIMM generated in an electronic device (comparative example) not including the conducting member 20A, whereas FIG. 10B shows a horizontal wave of high-frequency noises radiated from the DIMM 14 generated in the electronic device 1 (according to the embodiment) including the conducting member 20A.

The drawings indicate that a reduction of the noise level by 5 dB is realized by providing the conducting member 20A according to the embodiment since noise levels of the comparative example not having the conducting member 20A and the embodiment having the conducting member 20A are approximately 36 dB and 31 dB, respectively, at a peak of the high-frequency noises of approximately 930 MHz.

In addition, FIG. 11A shows a vertical wave of high-frequency noises radiated from a DIMM generated in an electronic device (comparative example) not including the conducting member 20A, whereas FIG. 11B shows a vertical wave of high-frequency noises radiated from the DIMM 14 generated in the electronic device 1 (according to the embodiment) including the conducting member 20A.

The drawings indicate that a reduction of the noise level by 3 dB is realized by providing the conducting member 20A according to the embodiment since noise levels of the comparative example not having the conducting member 20A and the embodiment having the conducting member 20A are approximately 37 dB and 34 dB, respectively, at a peak of the high-frequency noises of approximately 930 MHz.

Various alterations of the above-described electronic device 1 will now be described using FIGS. 6A to 8C. In FIGS. 6A to 8C, similar or like references are attached to elements commonly shown in FIGS. 1 to 5 used in the description of the electronic device 1, and a description of thereof is omitted.

FIG. 6A shows the conducting member 20A provided in the electronic device 1. In this conducting member 20A, a projecting portion 21A is formed to protrude upward by presswork (plastic working). On the other hand, a projecting portion 21B is formed by folding a leading end of an upper part 25 of a conducting member 20B according to an alteration shown in FIG. 6B.

With this configuration, the height of the projecting portion 21B can be flexibly adjusted and the elastic deformation degree of the projecting portion 21B can be set larger than that of the projecting portion 21A shown in FIG. 6A. Accordingly, even if the clearance ΔH1 between the upper face of the slot connector 12 and the cover 5 varies, this variation can be canceled and the reliability of the electrical connection between the conducting member 20B and the cover 5 can be increased. In particular, although the clearance ΔH1 between the upper face of the slot connector 12 and the cover 5 is likely to vary since the cover 5 is attached to and detached from the casing 2, the configuration of the conducting member 20B shown in FIG. 6B can cancel an influence of the variation.

In a conducting member 20C shown in FIG. 6C, a projecting portion 21C is formed in an inverted U-shape toward the cover 5. This configuration can realize advantages equivalent to those provided by the conducting member 20B shown in FIG. 6B. In addition, the entire length of the conducting member 20C can be set shorter than that of the conducting member 20B shown in FIG. 6B, which can reduce a cost for materials.

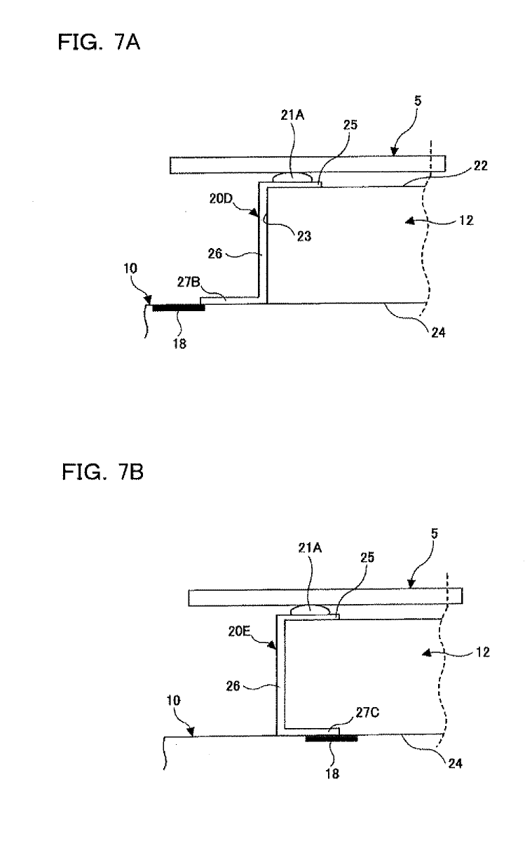

FIGS. 7A and 7B show alterations regarding a connection configuration of a board SG 18 and a conducting member. In the above-described electronic device 1, the board SG 18 is formed substantially directly beneath the arrangement position of the conducting member 20A. In this configuration, the lower part 27A of the conducting member 20A does not have to be routed on the printed circuit board 10.

However, the arrangement position of the slot connector 12 including the conducting member 20A may be shifted from the arrangement position of the board SG 18. FIG. 7A shows an example case where the board SG 18 is shifted outward (to the left in the drawing) from the arrangement position of the slot connector 12. In this case, a lower part 27B of the conducting member 20D extends to the arrangement position of the board SG 18 on the printed circuit board 10. In this manner, the lower part 27B is electrically connected to the board SG 18.

In addition, FIG. 7B shows an example case where the arrangement position of the board SG 18 is located under the arrangement position of the slot connector 12. In this case, a lower part 27C of a conducting member 20E curves to reach the lower face of the slot connector 12. In this manner, the lower part 27C is electrically connected to the board SG 18.

As described above, even if the arrangement position of the slot connector 12 on the printed circuit board 10 is shifted from the arrangement position of the board SG 18, the board SG 18 can be electrically connected to the conducting member 20D or 20E by appropriately changing a shape of the lower part 27B or 27C. Accordingly, the board SG 18 can be surely electrically connected to the cover 5 functioning as the casing FG.

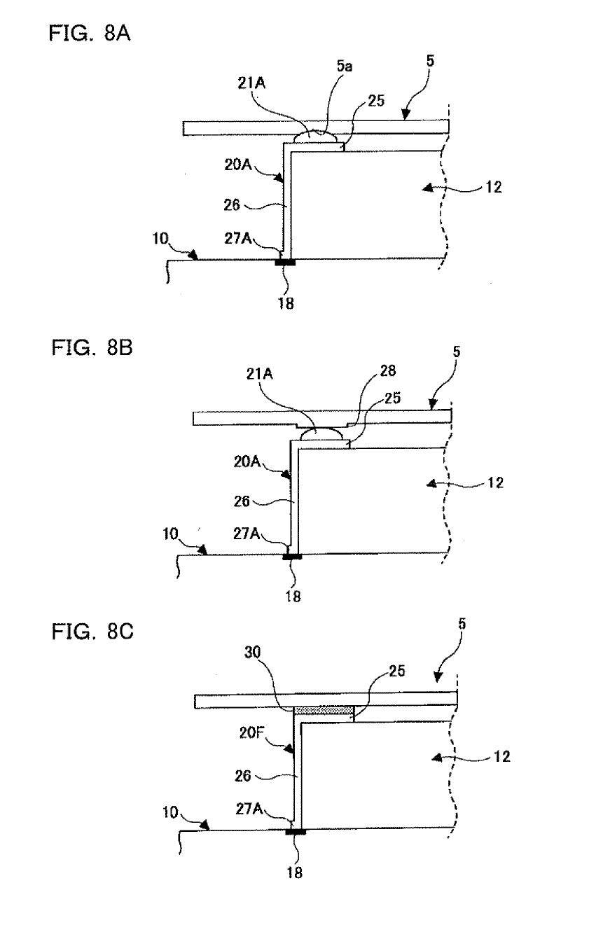

FIGS. 8A to 8C show alterations of a connection configuration of conducting members 20A and 20F and the cover 5. FIG. 8A shows an alteration in which a concave portion 5a is formed at a position of the cover 5 to which the projecting portion 21A is connected.

By forming the concave portion 5a in the cover 5 in this manner, an contact area of the projecting portion 21A and the cover 5 can be increased than that of a configuration not having the concave portion 5a when the projecting portion 21A is brought into engagement with the concave portion 5a. This permits the cover and the conducting member 20A to be electrically connected more certainly. Furthermore, when the cover 5 is attached to the casing 2, positioning of the cover 5 with respect to the casing 2 can be performed by the engagement of the projecting portion 21A with the concave portion 5a. Thus, the cover 5 can be easily attached to the casing 2.

In an alteration shown in FIG. 8B, a convex portion 28 is formed on the cover 5. When the clearance ΔH1 between the upper face of the slot connector 12 and the cover 5 is large, it can be considered that only the height of the projecting portion 21A formed in the conducting member 20A may be unable to bring the projecting portion 21A to abut against (be engaged with) the cover 5. However, by forming the convex portion 28 on the cover 5 as in this embodiment, it is possible to certainly electrically connect the projecting portion 21A to the cover 5.

Furthermore, in an alteration shown in FIG. 8C, a conductive tape 30 is provided between an upper part 25 of a conducting member 20F and the cover 5. The conductive tape 30 is formed of a resin material mixed with a conductive metal power. Thus, by interposing the conductive tape 30 between the upper part 25 and the cover 5, the board SG 18 can be electrically connected to the cover 5 through the conducting member 20F and the conductive tape 30. Since the conductive tape 30 can flexibly deform, the conductive tape 30 can absorb the variation even if the clearance ΔH1 between the upper face of the slot connector 12 and the cover 5 varies. Thus, the cover 5 can be certainly electrically connected to the conducting member 20F.

Although the embodiments of the present technique have been described above, the present technique is not limited to the above-described specific embodiments but can be variously altered and modified within a scope of the spirit of the present technique defined by the claims.

For example, a configuration in which the conducting members 20A to 20F are provided in the slot connector 12 to which one DIMM 14 is attached is shown in the above-described embodiments and alterations. However, the conducting member 20A may be provided in a double slot connector 32 to the respective (upper and lower) sides of which two DIMMs 14A and 14B are attached as shown in FIG. 9. As described above, it is possible to provide the conducting member regardless of the form of the slot.

Regarding the description given above, the following claims are further disclosed.

What is claimed is:

1. An electronic device comprising:
a casing having an opening;
a cover removably attached to the casing to cover the opening;
a slot mounted on a board arranged in the casing; and
a conducting member provided at the slot, the conducting member electrically connecting the board to the cover.

2. The device according to claim 1, wherein a portion of the conducting member that touches the cover has a projecting portion.

3. The device according to claim 2, wherein the projecting portion has elasticity.

4. The device according to claim 2, wherein a portion of the cover that touches the projecting portion is in a concave shape.

5. The device according to claim 3, wherein a portion of the cover that touches the projecting portion is in a concave shape.

6. The device according to claim 1, wherein the conducting member is a conductive tape.

7. A slot mounted on a board stored in a casing having an opening, the slot comprising:
a conducting member for electrically connecting a cover that covers the opening to the board having the slot mounted thereon.

8. The slot according to claim 7, wherein a portion of the conducting member that touches the cover has a projection.

9. The slot according to claim 8, wherein the projection has elasticity.

10. The slot according to claim 7 wherein the conducting member is a conductive tape.
